(19) United States
(12) Patent Application Publication
(10) Pub. No.: US 2014/0027735 A1
(43) Pub. Date: Jan. 30, 2014

(54) ORGANIC LIGHT EMITTING DIODE DISPLAY AND MANUFACTURING METHOD THEREOF

(71) Applicant: SAMSUNG DISPLAY CO., LTD., Yongin-city (KR)

(72) Inventors: Il-Nam KIM, Yongin-city (KR); Won-Sang PARK, Yongin-city (KR); Min-Woo KIM, Yongin-city (KR)

(73) Assignee: SAMSUNG DISPLAY CO., LTD., Yongin-city (KR)

(21) Appl. No.: 13/791,373

(22) Filed: Mar. 8, 2013

(30) Foreign Application Priority Data
Jul. 25, 2012 (KR) 10-2012-0081341

(51) Int. Cl. H01L 51/52; H01L 51/56

(52) U.S. Cl. CPC H01L 51/5275; H01L 51/56
USPC 257/40; 438/29

(57) ABSTRACT

Disclosed are an organic light emitting diode display and a manufacturing method thereof, and more particularly, an organic light emitting diode display and a manufacturing method thereof, that improve light extraction efficiency by forming a light controlling layer formed in a multilayer having different refractive indexes so that light is not absorbed in a pixel defining layer but reflected to the front side due to a refractive index difference.

### CROSS-REFERENCE TO RELATED APPLICATIONS

This application is based on and claims priority from Korean Patent Application No. 10-2012-0081341, filed on Jul. 25, 2012, with the Korean Intellectual Property Office, the present disclosure of which is incorporated herein in its entirety by reference.

### TECHNICAL FIELD

The present disclosure relates to an organic light emitting diode display and a manufacturing method thereof, and more particularly, to an organic light emitting diode display having improved light efficiency and a manufacturing method thereof.

### BACKGROUND

An organic light emitting diode display is a self-emission display device which has an organic light emitting diode which emits light to display an image. Since the organic light emitting diode display does not require a separate light source unlike a liquid crystal display, it is possible to relatively reduce thickness and weight thereof. Further, since the organic light emitting diode display has high-quality characteristics such as low power consumption, high luminance, and high response speed, the organic light emitting diode display receives attention as a next-generation display device for portable electronic apparatuses.

An organic light emitting diode is an element using light generated when an electron and a hole are coupled with each other to emit light and dissipate the emitted light. Generally, the organic light emitting diode basically includes an electrode for injecting a hole, an electrode for injecting an electron, and an emission layer, and has a structure in which the emission layer is laminated between a positive electrode which is the electrode for injecting a hole and a negative electrode which is the electrode for injecting an electron. When the electron is injected to the negative electrode of the organic light emitting diode and the hole is injected to the positive electrode, charges thereof move in opposite directions to each other by an external electric field and then are coupled with each other in the emission layer to emit light while light is emitted and emitted light is dissipated. In the organic light emitting diode, the emission layer is made of a single molecular organic material or a polymer.

FIG. 1 schematically illustrates a general structure of an organic light emitting diode.

Referring to FIG. 1, a structure of the organic light emitting diode including a base part 10, an insulating layer 20, a positive electrode 30, a pixel defining layer 40, an emission layer 60, and a negative electrode 70 is schematically illustrated. Here, the base part 10 includes a substrate and a TFT layer formed on the substrate. In some cases, a laminate including the substrate and the TFT layer is referred to as a substrate.

As described above, the organic light emitting diode display generally has a structure in which the positive electrode and the negative electrode are sequentially disposed on a flat insulating layer which covers a thin film transistor provided on the substrate, and a multilayered organic layer is interposed between the positive electrode and the negative electrode.

In the organic light emitting diode display, since the light is partially reflected or totally reflected between the organic layer and the electrodes, efficiency that the light generated from the organic layer is discharged outside is reduced. For example, the organic light emitting diode in the related art has only light efficiency of about 20% due to light reflection between the organic layer and the electrodes.

### SUMMARY

The present disclosure has been made in an effort to provide an organic light emitting diode display capable of improving light efficiency by forming a light controlling layer on a pixel defining layer and a manufacturing method thereof.

An example embodiment of the present disclosure provides an organic light emitting diode display, including: a substrate; an insulating layer disposed on the substrate; a first electrode disposed on the insulating layer; a pixel defining layer disposed on the insulating layer to define the first electrode by a pixel unit; a light controlling layer disposed on the pixel defining layer; an organic emission layer disposed on the first electrode; and a second electrode disposed on the organic emission layer.

The organic light emitting diode display may further include a semiconductor element disposed on the substrate and electrically connected with the first electrode. The semiconductor element may be a thin film transistor (TFT).

The insulating layer may have a concave portion including a bottom portion and an inclined portion, and the first electrode may be disposed through the bottom portion and the inclined portion of the concave portion, and the light controlling layer may comprise a multilayer, for example, 2 to 60 layers.

A side portion of the first electrode may be formed on the inclined portion of the concave portion, and the side portion of the first electrode may have the same inclined angle as the inclined portion of the concave portion.

The pixel defining layer may be overlapped with the side portion of the first electrode. In addition, the light controlling layer may be formed on the pixel defining layer to extend to a portion where the pixel defining layer is overlapped with the first electrode.

The light controlling layer may have a structure in which a layer having a high refractive index and a layer having a low refractive index are alternately laminated.

A refractive index of the layer having a high refractive index may be in the range of 1.6 to 1.8, and a refractive index of the layer having a low refractive index may be in the range of 1.4 to 1.6.

The light controlling layer may include at least one of an inorganic layer containing at least one selected from a group consisting of Au, Ag, Al, Ga and an alloy containing the same; and an organic layer containing at least one selected from organic materials having an acrylate group, a polyimide group, and silicon oxide.

The organic emission layer may be formed to extend from the upper portion of the first electrode to the side portion of the light controlling layer.

Another example embodiment of the present disclosure provides an organic light emitting diode display, including: a substrate; an insulating layer disposed on the substrate; a first electrode disposed on the insulating layer; a pixel defining layer disposed on the insulating layer to define the first electrode by a pixel unit; an organic emission layer disposed on the first electrode to extend to the upper portion of the pixel defining layer; a light controlling layer disposed on a portion of the organic emission layer extending to the pixel defining layer; a second electrode disposed on the light controlling layer and the organic emission layer; and a spacer disposed between the light controlling layer and the second electrode. Here, the light controlling layer may comprise a multilayer, for example, 2 to 60 layers.

The insulating layer may have a concave portion including a bottom portion and an inclined portion, and the first electrode may be disposed through the bottom portion and the inclined portion of the concave portion.

The organic light emitting diode display may further include a semiconductor element disposed on the substrate and electrically connected with the first electrode. The semiconductor element may be a thin film transistor (TFT).

A side portion of the first electrode may be formed on the inclined portion of the concave portion, and the side portion of the first electrode may have the same inclined angle as the inclined portion of the concave portion.

The pixel defining layer may be overlapped with the side portion of the first electrode.

The light controlling layer may have a structure in which a layer having a high refractive index and a layer having a low refractive index are alternately laminated.

A refractive index of the layer having the high refractive index may be in the range of 1.6 to 1.8, and a refractive index of the layer having the low refractive index may be in the range of 1.4 to 1.6.

The light controlling layer may include at least one of an inorganic layer containing at least one selected from a group consisting of Au, Ag, Al, Ga and an alloy containing the same; and an organic layer containing at least one selected from organic materials having an acrylate group, a polyimide group, and silicon oxide.

The light controlling layer may have an arch portion protruding toward the second electrode, and at least a part of the arch portion may be overlapped with the side portion of the first electrode.

Further, the present disclosure provides a manufacturing method of an organic light emitting diode display.

Yet another example embodiment of the present disclosure provides a manufacturing method of an organic light emitting diode display, including: forming an insulating layer on a substrate; forming a first electrode on the insulating layer; forming a pixel defining layer on the insulating layer so as to section the first electrode by a pixel unit; forming a light controlling layer on the pixel defining layer; forming an organic emission layer on the exposed first electrode; and forming a second electrode on the organic emission layer.

The forming of the insulating layer may include coating a material for the insulating layer on the entire surface of the substrate; and forming a concave portion having a bottom portion and an inclined portion on the coated material for the insulating layer.

In the forming of the first electrode, a side portion of the first electrode may be disposed on the inclined portion of the concave portion.

In the forming of the pixel defining layer, an end portion of the pixel defining layer may be formed to be overlapped with the side portion of the first electrode.

The light controlling layer may be formed to extend to the side portion of the pixel defining layer formed on a portion corresponding to the inclined portion of the concave portion.

The forming of the light controlling layer may include (a) forming a low refractive index layer on the pixel defining layer; (b) forming a high refractive index layer on the low refractive index layer; and (c) removing the low refractive index layer and the high refractive index layer formed on a portion corresponding to the bottom portion of the first electrode. Here, (a) and (b) steps may be performed two times or more. The (a) and (b) steps may be performed up to 30 times, and may be performed up to 60 times in some cases.

The forming of the light controlling layer may include at least one of forming an inorganic layer containing at least one selected from Au, Ag, Al, Ga and an alloy containing the same; and forming an organic layer containing at least one selected from organic materials having an acrylate group, a polyimide group, and silicon oxide.

The organic emission layer may be formed to extend from the upper portion of the first electrode to the side portion of the light controlling layer.

Still another example embodiment of the present disclosure provides a manufacturing method of an organic light emitting diode display, including: forming an insulating layer on a substrate; forming a first electrode on the insulating layer; forming a pixel defining layer on the insulating layer so as to section the first electrode by a pixel unit; forming an organic emission layer on the exposed first electrode to extend to a part of the pixel defining layer; forming a light controlling layer on a portion of the organic emission layer extending to the pixel defining layer; forming a spacer on the light controlling layer; and forming a second electrode on the spacer and the organic emission layer.

The forming of the insulating layer may include coating a material for the insulating layer on the entire surface of the substrate; and forming a concave portion having a bottom portion and an inclined portion on the coated material for the insulating layer.

In the forming of the first electrode, a side portion of the first electrode may be disposed on the inclined portion of the concave portion.

In the forming of the pixel defining layer, an end portion of the pixel defining layer may be formed to be overlapped with the side portion of the first electrode.

The organic emission layer may be formed to extend to the side portion of the pixel defining layer formed on a portion corresponding to the upper portion of the exposed first electrode and the inclined portion of the concave portion.

The light controlling layer may be formed to extend to the side portion of the organic emission layer.

The forming of the light controlling layer may include (a) forming a high refractive index layer on the organic emission layer; (b) forming a low refractive index layer on the high refractive index layer; and (c) removing the high refractive index layer and the low refractive index layer formed on a portion corresponding to the bottom portion of the organic emission layer. Here, (a) and (b) steps may be performed two times or more. For example, the (a) and (b) steps may be performed up to 30 times, and may be performed up to 60 times in some cases.

The forming of the light controlling layer may include at least one of forming an inorganic layer containing at least one selected from Au, Ag, Al, Ga and an alloy containing the same; and forming an organic layer containing at least one selected from organic materials having an acrylate group, a polyimide group, and silicon oxide.

According to the example embodiment of the present disclosure, by forming a nonconductive light controlling layer on a pixel defining layer, light in an organic light emitting diode display is not absorbed to the pixel defining layer but reflected to the front, such that it is possible to improve extraction efficiency of external light.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a diagram schematically illustrating an example for a general structure of an organic light emitting diode.

FIG. 2 is a diagram schematically illustrating a structure of an organic light emitting diode display according to an example embodiment of the present disclosure.

FIG. 3 is a diagram illustrating a schematic structure of a light controlling layer and a light extraction mechanism in the light controlling layer according to the example embodiment of the present disclosure.

FIG. 4 is a diagram schematically illustrating a structure of an organic light emitting diode display according to another example embodiment of the present disclosure.

FIGS. 5A to 5J are cross-sectional views for describing a manufacturing method of the organic light emitting diode display according to the example embodiment of the present disclosure.

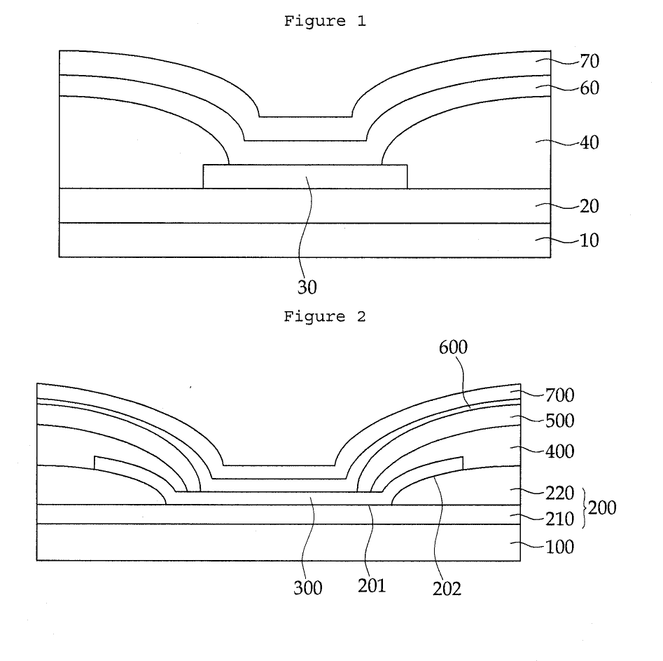

### DETAILED DESCRIPTION

Hereinafter, example embodiments of the present disclosure will be described in detail with reference to the accompanying drawings.

Although the present disclosure can be modified variously and have several embodiments, specific example embodiments are illustrated in the accompanying drawings and will be mainly described in the specification. However, the scope of the present disclosure is not limited to the specific embodiments and should be construed as including all the changes, equivalents, and substitutions included in the spirit and scope of the present disclosure.

Terms used in the present disclosure select normal terms which are widely used in present, but in some cases, a term which is arbitrarily selected by an applicant exists, and in this case, a meaning thereof should be understood by considering the meaning disclosed or used in detailed description of the present disclosure.

Parts which are not associated with the description are omitted in order to specifically describe the present disclosure and like reference numerals refer to like elements throughout the specification. Further, in the drawings, size and thickness of each element are arbitrarily illustrated for convenience of description, and the present disclosure is not necessarily limited to those illustrated in the drawings.

In the drawings, the thicknesses of layers and regions are enlarged for clarity. In the drawings, the thicknesses of a layer and a region are exaggerated for convenience of description. It will be understood that when an element such as layer, film, region, or substrate is referred to as being “on” another element, it can be directly on the other element or intervening elements may also be present.

FIG. 2 is a cross-sectional view schematically illustrating an organic light emitting diode display according to an example embodiment of the present disclosure.

As illustrated in FIG. 2, an organic light emitting diode display according to an example embodiment of the present disclosure basically includes a substrate 100; an insulating layer 200 disposed on the substrate; a first electrode 300 disposed on the insulating layer; a pixel defining layer 400 disposed on the insulating layer to define the first electrode by a pixel unit; a light controlling layer 500 disposed on the first electrode which is defined by a pixel unit; an organic emission layer 600 disposed on the light controlling layer; and a second electrode 700 disposed on the organic emission layer.

According to the present disclosure, the light controlling layer 500 is formed in a multilayer, but a single layer is illustrated in FIG. 2.

Further, in FIG. 2, for simplifying the description, a semiconductor element is not separately represented but omitted, but the semiconductor element may be disposed between the substrate 100 and the insulating layer 200. An example of the semiconductor element is a thin film transistor (TFT) including a gate electrode, a source electrode, and a drain electrode.

In FIG. 2, a case where the first electrode is a positive electrode is exemplified, and the first electrode 300 as the positive electrode may be electrically connected with the drain electrode of the thin film transistor (TFT). The semiconductor element may be formed by a general method of forming the thin film transistor. Accordingly, the description for a detailed method of forming the semiconductor element or the thin film transistor is omitted.

As illustrated in FIG. 2, the insulating layer is disposed on the substrate 100.

The substrate 100 may be made of various materials such as glass, metal, and plastic and may be formed by using a flexible material. In the case of a rear emission in which an image is implemented in a substrate direction, the substrate needs to be made of a light transmissive material, but in the case of a front emission, the substrate is not necessarily made of the light transmissive material.

According to the example embodiment of the present disclosure, a transparent insulation substrate may be used as the substrate 100. For example, the substrate 100 may be configured by a glass substrate, a quartz substrate, a transparent resin substrate, and the like. The transparent resin substrate which may be used as the substrate 100 may include a polyimide resin, an acrylic resin, a polyacrylate resin, a polycarbonate resin, a polyether resin, a polyethylene terephthalate resin, a sulfonic acid resin, and the like. These resins may be used either alone or in combination thereof.

According to the example embodiment of the present disclosure, a lower structure including a switching element, a contact pad, a plug, an electrode, a conductive pattern, an insulation pattern, and the like may be provided on the substrate. In this case, the insulating layer 200 may have a thickness enough to cover the lower structures.

The insulating layer 200 may be formed in a single structure, but may be formed in a multilayer structure including two or more insulating layers.

For example, as illustrated in FIG. 2, the insulating layer 200 may include a first insulating layer 210 and a second insulating layer 220 which are sequentially formed on the substrate 100. In this case, the first insulating layer 210 and the second insulating layer 220 may be formed by using substantially the same or similar material. Of course, the first insulating layer 210 and the second insulating layer 220 may be formed by using different materials.

According to the example embodiment of the present disclosure, in order to improve flatness of the insulating layer 200 formed on the substrate, a planarization process may be performed on the substrate. For example, a chemical mechanical polishing (CMP) process, an etch-back process, and the like are performed on the substrate and thus the substrate may have a flat upper surface.

According to the example embodiment of the present disclosure, the insulating layer 200 may contain an organic material. For example, the insulating layer 200 may contain a material selected from photoresist, acrylate-based polymer, polyimide-based polymer, polyamide-based polymer, siloxane-based polymer, polymer containing a photosensitive acryl carboxyl group, a novolac resin, and an alkali developable resin. These materials may be used either alone or in combination thereof.

According to another example embodiment of the present disclosure, the insulating layer 200 may be formed by using an inorganic material such as silicon compound, metal, metal oxide, and the like. For example, the insulating layer 200 may contain a material selected from silicon oxide (SiOx), silicon nitride (SiNx), silicon oxynitride (SiOxNy), silicon oxycarbide (SiOxCy), silicon carbonitride (SiCxNy), aluminum (Al), magnesium (Mg), zinc (Zn), hafnium (Hf), zirconium (Zr), titanium (Ti), tantalum (Ta), aluminum oxide (AlOx), titanium oxide (TiOx), tantalum oxide (TaOx), magnesium oxide (MgOx), zinc oxide (ZnOx), hafnium oxide (HfOx), zirconium oxide (ZrOx), and titanium oxide (TiOx). These materials may be used either alone or in combination thereof.

The insulating layer 200 may formed on the substrate by using a spin coating process, a printing process, a sputtering process, a chemical vapor deposition (CVD) process, an atomic layer deposition (ALD) process, a plasma enhanced chemical vapor deposition (PECVD) process, a high density plasma-chemical vapor deposition (HDP-CVD) process, a vacuum deposition process, and the like according to a constituent material.

As illustrated in FIG. 2, the insulating layer 200 may have a concave portion. In the case where the insulating layer 200 has the concave portion, the organic light emitting diode display including the insulating layer 200 may have a front emission mode. The concave portion has a concaved bottom portion 201 and an inclined portion 202 which is a side portion having an inclination.

In FIG. 2, the concave portion is formed by the first insulating layer 210 and the second insulating layer 220. In this case, the first insulating layer 210 forms the bottom portion 201, and the side portion of the second insulating layer 220 forms the inclined portion 202.

The first electrode 300 is formed on the insulating layer 200 having the inclined portion 202. The first electrode 300 is formed throughout the inclined portion 202 which is the side portion of the concave portion and the bottom portion 201. In other words, the side portion of the first electrode 300 may be formed at the inclined portion of the concave portion. Accordingly, the side portion of the first electrode 300 which is disposed at the inclined portion 202 may have substantially the same or similar inclined angle as or to the inclined portion of the concave portion. For example, an inclined angle of the side portion of the first electrode 300 which is disposed on the inclined portion 202 may be about 20° to about 70° with respect to a substantially parallel direction to the substrate 100 surface.

In the case where the organic light emitting diode display has a front emission mode, the first electrode 300 may be formed by using a reflective material. For example, the first electrode 300 may contain a material selected from metal such as aluminum, silver, platinum, gold (Au), chromium, tungsten, molybdenum, titanium, palladium (Pd), and iridium (Ir), and an alloy thereof. These materials may be used either alone or in combination thereof. Further, the first electrode 300 may be formed in a single layer structure or multilayer structure containing the above metal and/or the alloy.

According to the example embodiment of the present disclosure, the first electrode 300 may be formed on a part of the insulating layer 200 by forming a first electrode layer on the front surface of the insulating layer 200 and then patterning the first electrode layer. Here, the first electrode layer may be formed by a method such as a sputtering process, a vacuum deposition process, a chemical vapor deposition process, a pulse laser deposition process, a printing process, and an atomic layer deposition process using a material configuring the first electrode 300. As described below, the first electrode 300 may extend up to a part of an adjacent non-luminescent region based on a luminescent region of the organic light emitting diode display.

In other example embodiments, a through-hole which is connected to the semiconductor element through the insulating layer 200 may be formed in the insulating layer 200. A part of the semiconductor element is exposed by the through-hole, a contact structure or a pad structure is formed in the through-hole and on the exposed semiconductor element, for example, the thin film transistor (TFT), and the first electrode 300 formed on the insulating layer 200 may be connected to the contact structure or the pad structure. Accordingly, the first electrode 300 may be electrically connected to the semiconductor element through the contact structure or the pad structure.

Next, the pixel defining layer 400 is formed on the insulating layer 200 and the first electrode 300. The pixel defining layer 400 may be formed by using an organic material, an inorganic material, and the like. For example, the pixel defining layer 400 may contain a material selected from an organic material such as photoresist, a polyacryl-based resin, a polyimide-based resin, and an acryl-based resin or an inorganic material such as silicon compound.

A material for forming the pixel defining layer is coated on the first electrode 300 and the entire upper portion of the insulating layer 200 and then partially etched to form the pixel defining layer 400 so that a part of the first electrode 300 is exposed. For example, the first electrode 300 may be exposed by using a photolithography process or an etching process using an additional etching mask. In the example embodiments, a side wall of an opening of the pixel defining layer 400 may have substantially the same or similar inclined angle as or to an inclined angle of the inclined portion of the insulating layer. For example, the side wall of the opening of the pixel defining layer 400 may have an inclined angle of about 20° to about 70° with respect to a substantially horizontal direction to the substrate 100.

As the pixel defining layer 400 is formed, the luminescent region and the non-luminescent region of the organic light emitting diode display are defined. For example, a region where the pixel defining layer 400 does not exist corresponds to the luminescent region, and a region where the pixel defining layer 400 exists corresponds to the non-luminescent region.

The luminescent region is disposed at the concave portion of the insulating layer 200 in FIG. 2, and in the luminescent region, the first electrode 300 may be uniformly formed on the bottom portion 201 and the inclined portion 202 of the concave portion.

The pixel defining layer 400 partially extends between the first electrodes and up to the luminescent region to be formed on a part of the bottom portion of the first electrode 300 and the inclined portion of the side wall. In other words, in the luminescent region, the pixel defining layer 400 is also formed on the inclined portion which is the side portion of the first electrode 300. Accordingly, the part (for example, the side wall of the opening) of the pixel defining layer 400 disposed in the luminescent region may also have substantially the same or similar inclined angle as or to the inclined angle of the inclined portion 202. For example, the pixel defining layer 400 disposed in the luminescent region may be disposed on the part of the first electrode 300 at an inclined angle of about 20° to about 70° with respect to a substantially parallel axial line to the substrate 100.

As described above, after the pixel defining layer 400 is formed, the light controlling layer 500 is formed above a position corresponding to the inclined portion 202 of at least the concave portion in the area of the pixel defining layer 400.

According to the example embodiment of the present disclosure, the light controlling layer 500 is formed by a multilayer in which a layer having a low refractive index (hereinafter, referred to as a ‘low refractive layer’) and a layer having a high refractive index (hereinafter, referred to as a ‘high refractive layer’) are alternately laminated.

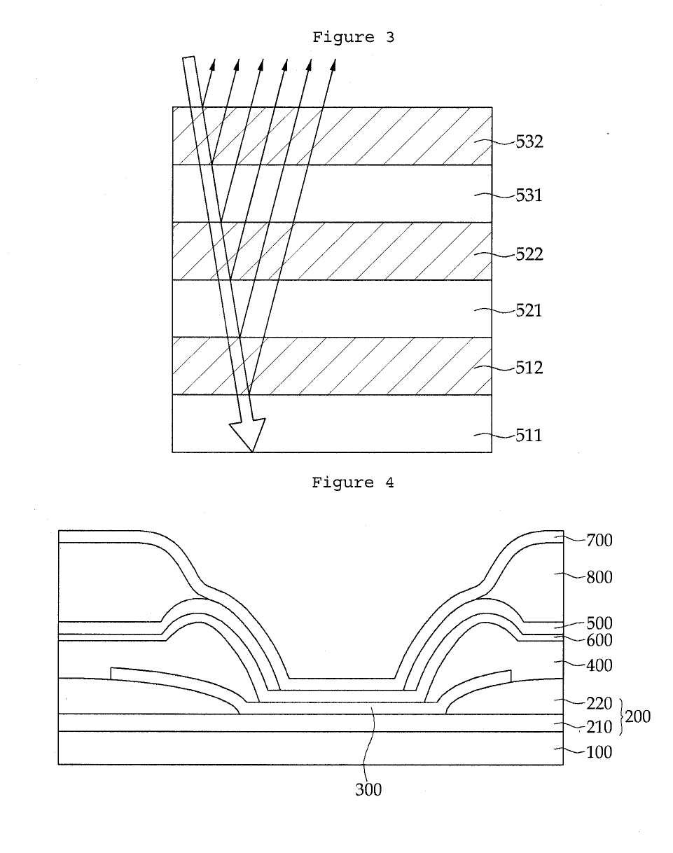

For example, as illustrated in FIG. 3, the light controlling layer 500 may be formed by a multilayer in which low refractive layers 511, 521, and 531 and high refractive layers 512, 522, and 532 are alternately laminated.

As such, in the case where the multilayer is made of materials having different refractive indexes, light extraction efficiency may be improved due to a difference in a refractive index. In general, the organic material and the inorganic material have different refractive indexes according to a kind thereof. Further, the refractive index may depend on a deposition condition. Accordingly, in order to form the light controlling layer 500, if only the refractive indexes are different, the light controlling layer 500 may be formed in combinations of inorganic material/organic material, inorganic material/inorganic material, and organic material/organic material.

In a general organic light emitting diode (OLED), since a refractive index of the pixel defining layer is 1.5 and a refractive index of the second electrode is 1.7, it is most effective to use a material capable of having a difference in a refractive index while the refractive index is in the range of 1.5 to 1.7.

According to the example embodiment of the present disclosure, in the light controlling layer 500, the range of the refractive index of the high refractive layer is 1.6 to 1.8, and the range of the refractive index of the low refractive layer is 1.4 to 1.6.

In this case, the light controlling layer 500 may include at least one of an inorganic layer containing at least one selected from a group consisting of Au, Ag, Al, Ga and an alloy containing the same; and an organic layer containing at least one selected from organic materials having an acrylate group, a polyimide group, and silicon oxide.

While the light controlling layer moves to a horizontal side due to total reflection, a path of the dissipated light is changed and may be irradiated to a display surface.

Further, the light controlling layer 500 is formed in a multilayer structure in order to change a light path by generating reflection in all wavelengths. Here, for convenience of description, when the low refractive layer and the high refractive layer are represented by a pair, for a light extraction effect by the light controlling layer 500, as illustrated in FIG. 3, the low refractive layer and the high refractive layer may be formed by two pairs or more or three pairs or more. In some cases, the low refractive layer and the high refractive layer may be formed by 30 pairs, and if necessary, may be formed by 30 pairs or more.

Next, the organic emission layer 600 is formed on the exposed first electrode 300 and the light controlling layer 500.

The organic emission layer 600 may be formed by using emission materials capable of generating different color light such as red light, green light, and blue light according to each pixel of the organic light emitting diode display. According to another example embodiment, the organic emission layer 600 may have a multilayer structure which emits white light by laminating a plurality of emission materials capable of implementing different color lights such as red light, green light, and blue light. According to another example embodiment, the organic emission layer 600 may additionally include a host material having a substantially large band gap as compared with the emission materials.

According to the example embodiment of the present disclosure, the organic emission layer 600 is positioned on the first electrode 300 formed at the concave portion. Further, the organic emission layer 600 extends from the first electrode 300 in the luminescent region to be also formed above the light controlling layer 500. For example, as illustrated in FIG. 2, the bottom of the organic emission layer 600 is positioned on the first electrode 300, and the side of the organic emission layer 600 contacts the light controlling layer 500. Accordingly, the side of the organic emission layer 600 may also have substantially the same or similar inclined angle as or to the inclined angle of the inclined portion 202. For example, the side of the organic emission layer 600 may have an inclined angle of about 20° to about 70° with respect to a substantially parallel surface to the substrate 100 surface.

According to the example embodiment of the present disclosure, a first emission auxiliary layer may be formed between the first electrode 300 and the organic emission layer 600. In this case, the first emission auxiliary layer may include at least one of a hole injection layer and a hole transport layer. A second emission auxiliary layer may be formed between the organic emission layer 600 and the second electrode. In this case, the second emission auxiliary layer may include at least one of an electron injection layer and an electron transport layer.

Next, the second electrode 700 is formed on the organic emission layer 600. The second electrode 700 may be formed on the organic emission layer 600 at a regular thickness. In the case where the organic light emitting diode display has a front emission mode, the second electrode 700 may be formed by using a light transmissive conductive material. For example, the second electrode 700 may contain at least one of indium tin oxide, indium zinc oxide, zinc tin oxide, zinc oxide, tin oxide, and gallium oxide. These materials may be used either alone or in combination thereof.

According to the example embodiment of the present disclosure, the second electrode 700 may extend from the luminescent region to the non-luminescent region. According to another example embodiment, the second electrode 700 may be positioned only in the luminescent region. For example, the second electrode 700 may be formed on a part of the organic emission layer 600 (for example, the side of the organic emission layer 600). In this case, a second electrode layer (not illustrated) is formed all over the surface on the organic emission layer 600 and then patterned to form the second electrode 700 so as to be selectively disposed only in the luminescent region.

The second electrode 700 may also have substantially the same or similar inclined angle as or to the inclined angle in the luminescent region according to an inclined angle of the inclined portion 202 of the insulating layer 200. For example, the side of the second electrode 140 which is disposed on the organic emission layer 600 of the luminescent region may have an inclined angle of about 20° to about 70° with respect to a substantially parallel direction to the substrate 100 surface.

FIG. 4 is a diagram schematically illustrating a structure of an organic light emitting diode display according to another example embodiment of the present disclosure, and the organic light emitting diode display is a rear emission type.

As illustrated in FIG. 4, an organic light emitting diode display according to another example embodiment of the present disclosure basically includes a substrate 100; an insulating layer 200 disposed on the substrate; a first electrode 300 disposed on the insulating layer; a pixel defining layer 400 disposed on the insulating layer to define the first electrode by a pixel unit; an organic emission layer 600 disposed on the first electrode which is defined by a pixel unit; a light controlling layer 500 disposed on the organic emission layer; a second electrode 700 disposed on the light controlling layer; and a spacer 800 disposed between the light controlling layer and the second electrode. Here, the light controlling layer 500 is formed in a multilayer, but is illustrated as a single layer in FIG. 4.

A structure of the organic light emitting diode display illustrated in FIG. 4 has the same structure as that of the organic light emitting diode display illustrated in FIG. 2 above except that an order of the light controlling layer 500 and the organic emission layer 600 is shifted, and a spacer 800 layer is formed between the light controlling layer 500 and the second electrode 700.

According to the example embodiment of the present disclosure, the light controlling layer 500 is formed on the organic emission layer 600, and the spacer 800 is formed on the light controlling layer 500.

Referring to FIG. 4, the spacer 800 is formed in a protruding shape above the light controlling layer 500. The spacer 800 is required to prevent a panel of the organic light emitting diode display from being damaged due to external pressure. For example, the panel of the organic light emitting diode display has a space at the upper portion by forming the spacer 800 to prevent the organic light emitting diode display panel from being damaged due to external pressure.

Further, the spacer 800 may comprise at least one selected from polyimide and equivalents thereof, but here, a material of the spacer is not limited.

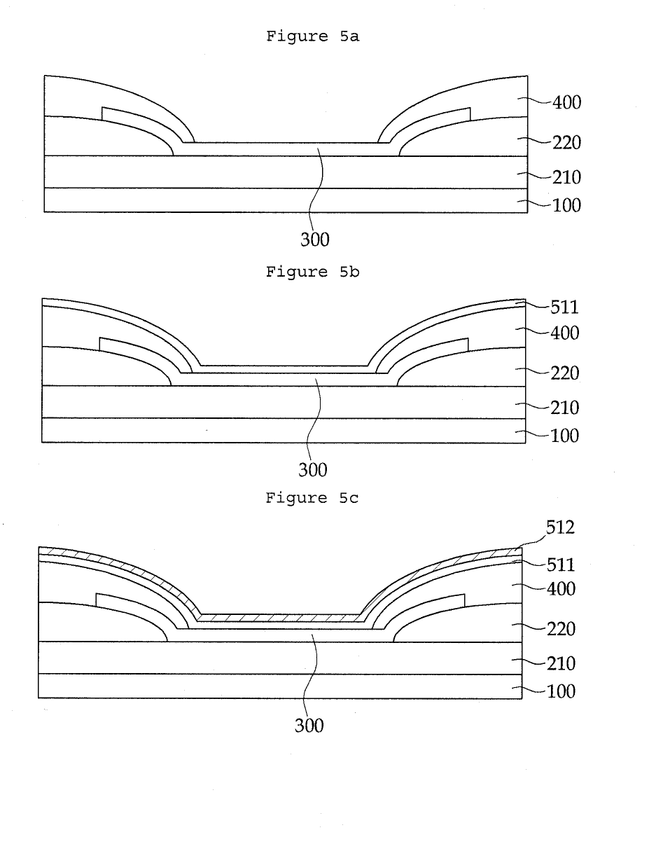

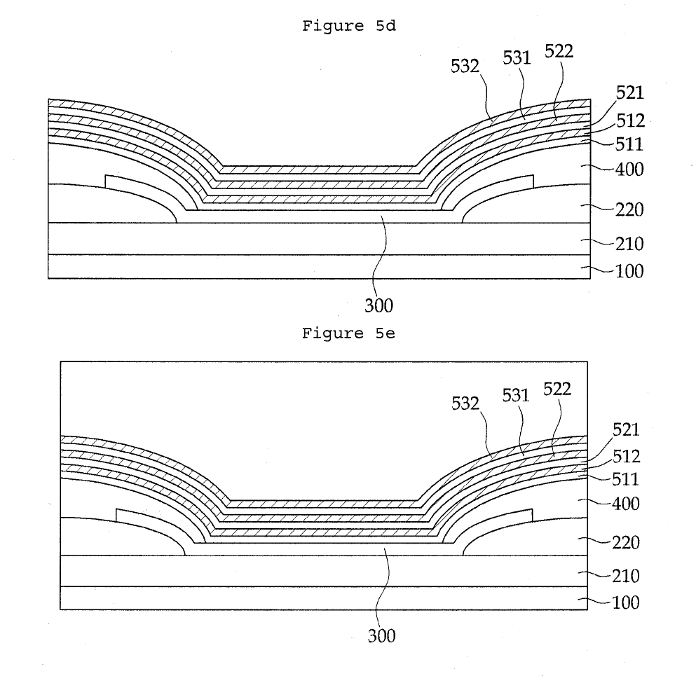

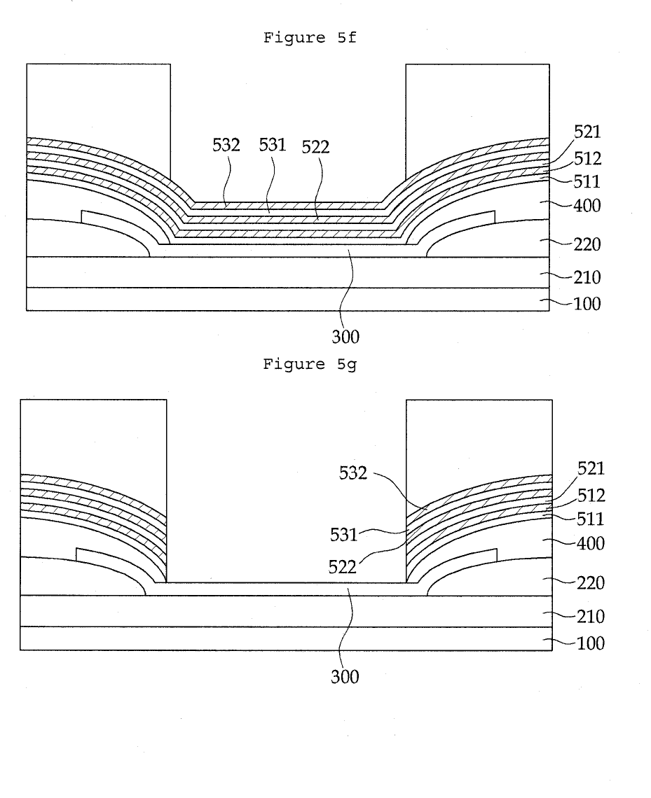

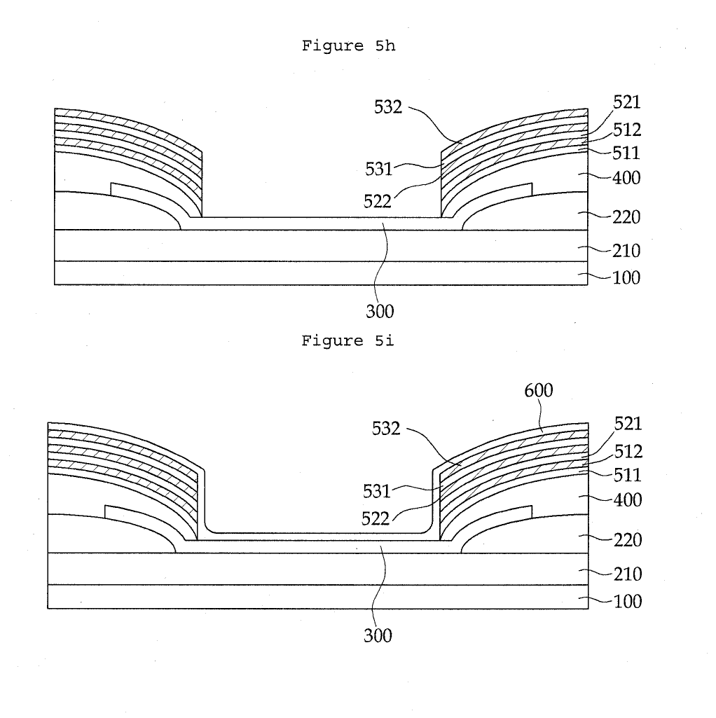

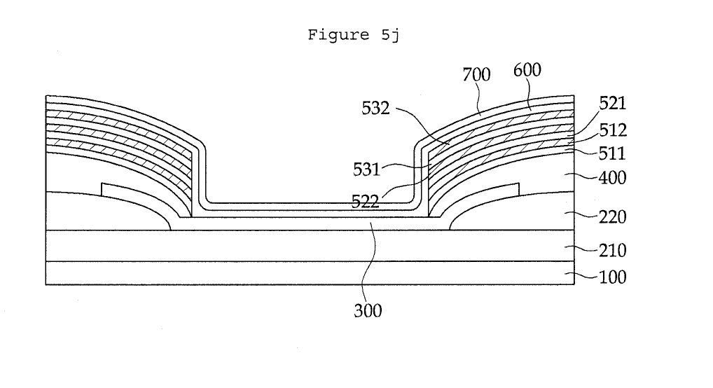

FIGS. 5A to 5J are cross-sectional views schematically illustrating an example of a manufacturing method of the organic light emitting diode display according to the example embodiment of the present disclosure.

In an example illustrated in FIGS. 5A to 5J, a case of including the first insulating layer 210 and the second insulating layer 220 as the insulating layer 200 is exemplified.

First, the first insulating layer 210 is formed on the substrate 100, and the second insulating layer 220 having the inclined portion 202 is formed on the first insulating layer 210 formed on the substrate 100.

In order to form the second insulating layer 220 having the inclined portion 202, first, the second insulating layer 220 is formed on the entire surface of the first insulating layer 210 and then partially removed to form a plurality of concave portions having the bottom portion 201 and the inclined portion 202.

Here, when the second insulating layer 220 is partially removed, the second insulating layer 220 is partially removed up to a portion contacting the first insulating layer 210 so that an inclination is formed at the side of the removed portion. As such, a concave portion is formed by partially removing the second insulating layer 220, and the inclined portion 202 is formed at the side portion of the concave portion. Here, the bottom portion 201 of the concave portion becomes the first insulating layer 210.

Next, the first electrode 300 is formed through the bottom portion 201 and the inclined portion 202 of the concave portion. In this case, the first electrode 300 is formed through the entire bottom portion 201 and the entire inclined portion 202 of the concave portion, and in addition, an end portion of the first electrode 300 partially extends up to the upper portion of the insulating layer (second insulating layer). Here, a portion of the first electrode 300 formed on the inclined portion 202 of the concave portion is referred to as the side portion of the first electrode 300.

Next, the pixel defining layer 400 is formed to section the first electrode 300 by a pixel unit. The pixel defining layer 400 is formed to extend up to the upper portion of the insulating layer (second insulating layer 220) and the side portion of the first electrode 300. For example, the pixel defining layer 400 is formed to cover a space between the first insulating layers 210 and a part of the first insulating layer 210.

A portion which is not covered by the pixel defining layer 400 is referred to as an opening or an opening of the first electrode 300.

FIGS. 5B to 5H are diagrams for describing a method of forming the light controlling layer 500 on the pixel defining layer 400. The light controlling layer 500 is formed in a multilayer in which a low refractive layer and a high refractive layer are alternately laminated, and the structure illustrated in FIGS. 5B to 5H has the light controlling layer 500 formed of three pairs of low refractive layers and high refractive layers.

Referring to FIGS. 5B and 5E, the light controlling layer 500 is formed on the pixel defining layer 400 formed by the above-described method.

First, a low refractive material is deposited on the pixel defining layer 400 to form a low refractive layer 511 (see FIG. 5B).

Next, a high refractive material is deposited on the low refractive layer 511 to form a high refractive layer 512 (see FIG. 5C).

The processes illustrated in FIGS. 5B and 5C are repeated two times to form the light controlling layer 500 configured of three pairs of low refractive layers 511, 521, and 531 and high refractive layers 512, 522, and 532 (see FIG. 5D).

Thereafter, a photoresist is coated on the light controlling layer 500 formed as described above (see FIG. 5E).

The coated photoresist is etched by a photolithography and developed so that the bottom portion of the first electrode 300 is exposed (see FIGS. 5F to 5H).

Next, as illustrated in FIG. 5I, the organic emission layer 600 is formed on the upper portion of the exposed first electrode 300 and the side portion of the light controlling layer 500. In this case, the organic emission layer 600 may be formed to extend to the upper portion of the first electrode 300 and the side portion of the light controlling layer 500. Further, as shown in FIG. 5J, the second electrode 700 is formed on the organic emission layer 600.

According to the example embodiment of the present disclosure, a first emission auxiliary layer may be formed between the first electrode 300 and the organic emission layer 600. In this case, the first emission auxiliary layer may include at least one of a hole injection layer and a hole transport layer. A second emission auxiliary layer may be formed between the organic emission layer 600 and the second electrode. In this case, the second emission auxiliary layer may include at least one of an electron injection layer and an electron transport layer.

In an organic light emitting diode display including a lower electrode, an organic emission layer, and an upper electrode in the related art, light generated from the organic emission layer is totally reflected between the organic emission layer and the upper and lower electrodes and as a result, light loss of substantially about 20% or more occurs.

On the contrary, according to the example embodiment of the present disclosure, by forming a nonconductive light controlling layer 500 formed in a multilayer made of materials having different refractive indexes, light in the organic light emitting diode display is not absorbed in the pixel defining layer 400 but reflected to the front side due to a refractive index difference to improve extraction efficiency of external light. As a result, the organic light emitting diode display according to the present disclosure may ensure increased light efficiency as compared with the organic light emitting diode display in the related art.

Further, the organic light emitting diode display according to the example embodiment of the present disclosure does not need to have a relatively complicated structure for optical resonance of the light generated from the organic emission layer 500 and thus may have a more simplified configuration as compared with the organic light emitting diode display in the related art having an optical resonance structure.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An organic light emitting diode display, comprising:
a substrate;
an insulating layer disposed on the substrate;
a first electrode disposed on the insulating layer;
a pixel defining layer disposed on the insulating layer;
a light controlling layer disposed on the pixel defining layer;
an organic emission layer disposed on the first electrode; and
a second electrode disposed on the organic emission layer.

2. The organic light emitting diode display of claim 1, wherein the light controlling layer is formed of 2 to 60 layers.

3. The organic light emitting diode display of claim 1, further comprising:
a semiconductor element disposed on the substrate and electrically connected to the first electrode.

4. The organic light emitting diode display of claim 1, wherein the insulating layer has a concave portion including a bottom portion and an inclined portion.

5. The organic light emitting diode display of claim 4, wherein the first electrode is disposed through the bottom portion and the inclined portion of the concave portion.

6. The organic light emitting diode display of claim 5, wherein a side portion of the first electrode is formed on the inclined portion of the concave portion, and the side portion of the first electrode has the same inclined angle as the inclined portion of the concave portion.

7. The organic light emitting diode display of claim 1, wherein the pixel defining layer overlaps the side portion of the first electrode, and the light controlling layer extends up to a portion where the pixel defining layer overlaps the first electrode.

8. The organic light emitting diode display of claim 1, wherein the light controlling layer has a structure in which a layer having a high refractive index and a layer having a low refractive index are alternately laminated.

9. The organic light emitting diode display of claim 8, wherein a refractive index of the layer having the high refractive index is in the range of 1.6 to 1.8, and a refractive index of the layer having the low refractive index is in the range of 1.4 to 1.6.

10. The organic light emitting diode display of claim 1, wherein the light controlling layer includes at least one of an inorganic layer containing at least one selected from a group consisting of Au, Ag, Al, Ga and an alloy containing the same; and an organic layer containing at least one selected from organic materials having an acrylate group, a polyimide group, and silicon oxide.

11. The organic light emitting diode display of claim 1, wherein the organic emission layer extends from the upper portion of the first electrode to the side portion of the light controlling layer.

12. An organic light emitting diode display, comprising:
a substrate;
an insulating layer disposed on the substrate;
a first electrode disposed on the insulating layer;
a pixel defining layer disposed on the insulating layer;
an organic emission layer disposed on the first electrode configured to extend to the upper portion of the pixel defining layer;
a light controlling layer disposed on a portion of the organic emission layer extending to the upper portion of the pixel defining layer;
a second electrode disposed on the light controlling layer and the organic emission layer; and
a spacer disposed between the light controlling layer and the second electrode.

13. The organic light emitting diode display of claim 12, wherein the light controlling layer is formed of 2 to 60 layers.

14. The organic light emitting diode display of claim 12, further comprising:
a semiconductor element disposed on the substrate and electrically connected to the first electrode.

15. The organic light emitting diode display of claim 12, wherein the insulating layer has an concave portion including a bottom portion and an inclined portion.

16. The organic light emitting diode display of claim 15, wherein the first electrode is disposed through the bottom portion and the inclined portion of the concave portion.

17. The organic light emitting diode display of claim 16, wherein a side portion of the first electrode is formed on the inclined portion of the concave portion, and the side portion of the first electrode has the same inclined angle as the inclined portion of the concave portion.

18. The organic light emitting diode display of claim 12, wherein the pixel defining layer overlaps the side portion of the first electrode.

19. The organic light emitting diode display of claim 12, wherein the light controlling layer has a structure in which a layer having a high refractive index and a layer having a low refractive index are alternately laminated.

20. The organic light emitting diode display of claim 19, wherein a refractive index of the layer having the high refractive index is in the range of 1.6 to 1.8, and a refractive index of the layer having the low refractive index is in the range of 1.4 to 1.6.

21. The organic light emitting diode display of claim 12, wherein the light controlling layer includes at least one of an inorganic layer containing at least one selected from a group consisting of Au, Ag, Al, Ga and an alloy containing the same; and an organic layer containing at least one selected from organic materials having an acrylate group, a polyimide group, and silicon oxide.

22. The organic light emitting diode display of claim 12, wherein the light controlling layer has an arch portion protruding toward the second electrode, and at least a part of the arch portion overlaps the side portion of the first electrode.

23. A manufacturing method of an organic light emitting diode display, comprising:
forming an insulating layer on a substrate;
forming a first electrode on the insulating layer;
forming a pixel defining layer on the insulating layer so as to section the first electrode by a pixel unit;
forming a light controlling layer on the pixel defining layer;
forming an organic emission layer on the exposed first electrode; and
forming a second electrode on the organic emission layer.

24. The manufacturing method of an organic light emitting diode display of claim 23, wherein the forming of the insulating layer includes coating a material for the insulating layer on the entire surface of the substrate; and forming a concave portion having a bottom portion and an inclined portion on the coated material for the insulating layer.

25. The manufacturing method of an organic light emitting diode display of claim 24, wherein in the forming of the first electrode, a side portion of the first electrode is disposed on the inclined portion of the concave portion.

26. The manufacturing method of an organic light emitting diode display of claim 23, wherein in the forming of the pixel defining layer, an end portion of the pixel defining layer overlaps the side portion of the first electrode.

27. The manufacturing method of an organic light emitting diode display of claim 24, wherein the light controlling layer extends to the side portion of the pixel defining layer formed on a portion corresponding to the inclined portion of the concave portion.

28. The manufacturing method of an organic light emitting diode display of claim 23, wherein the forming of the light controlling layer includes (a) forming low refractive index layers on the pixel defining layer and the first electrode; (b) forming high refractive index layers on the low refractive index layers; and (c) removing the low refractive index layer and the high refractive index layer formed on a portion corresponding to the bottom portion of the first electrode.

29. The manufacturing method of an organic light emitting diode display of claim 28, wherein (a) and (b) steps are performed two times or more.

30. The manufacturing method of an organic light emitting diode display of claim 23, wherein the forming of the light controlling layer includes at least one of forming an inorganic layer containing at least one selected from Au, Ag, Al, Ga and an alloy containing the same; and forming an organic layer containing at least one selected from organic materials having an acrylate group, a polyimide group, and silicon oxide.

31. The manufacturing method of an organic light emitting diode display of claim 23, wherein the organic emission layer is formed to extend from the upper portion of the first electrode to the side portion of the light controlling layer.

32. A manufacturing method of an organic light emitting diode display, comprising:
forming an insulating layer on a substrate;
forming a first electrode on the insulating layer;
forming a pixel defining layer on the insulating layer so as to section the first electrode by a pixel unit;
forming an organic emission layer on the exposed first electrode to extend to a part of the pixel defining layer;
forming a light controlling layer on a portion of the organic emission layer extending to the pixel defining layer;
forming a spacer on the light controlling layer; and
forming a second electrode on the spacer and the organic emission layer.

33. The manufacturing method of an organic light emitting diode display of claim 32, wherein the forming of the insulating layer includes coating a material for the insulating layer on the entire surface of the substrate; and forming a concave portion having a bottom portion and an inclined portion on the coated material for the insulating layer.

34. The manufacturing method of an organic light emitting diode display of claim 33, wherein in the forming of the first electrode, a side portion of the first electrode is disposed on the inclined portion of the concave portion.

35. The manufacturing method of an organic light emitting diode display of claim 32, wherein in the forming of the pixel defining layer, an end portion of the pixel defining layer overlaps the side portion of the first electrode.

36. The manufacturing method of an organic light emitting diode display of claim 33, wherein the organic emission layer extends to the side portion of the pixel defining layer formed on a portion corresponding to the upper portion of the exposed first electrode and the inclined portion of the concave portion.

37. The manufacturing method of an organic light emitting diode display of claim 32, wherein the forming of the light controlling layer includes (a) forming a high refractive index layer on the organic emission layer; (b) forming a low refractive index layer on the high refractive index layer; and (c) removing the high refractive index layer and the low refractive index layer formed on a portion corresponding to the bottom portion of the organic emission layer.

38. The manufacturing method of an organic light emitting diode display of claim 37, wherein (a) and (b) steps are performed two times or more.

39. The manufacturing method of an organic light emitting diode display of claim 32, wherein the forming of the light controlling layer includes at least one of forming an inorganic layer containing at least one selected from Au, Ag, Al, Ga and an alloy containing the same; and forming an organic layer containing at least one selected from organic materials having an acrylate group, a polyimide group, and silicon oxide.
